(19) United States
(12) Patent Application Publication
(10) Pub. No.: US 2018/0040278 A1
(43) Pub. Date: Feb. 8, 2018

(54) DISPLAY DEVICE

(71) Applicants: Hsia-Ching CHU, Miao-Li County (TW); Ming-Chien SUN, Miao-Li County (TW)

(72) Inventors: Hsia-Ching CHU, Miao-Li County (TW); Ming-Chien SUN, Miao-Li County (TW)

(21) Appl. No.: 15/667,652

(22) Filed: Aug. 3, 2017

(30) Foreign Application Priority Data
Aug. 3, 2016 (CN) 201610626922.2

(51) Int. Cl. G09G 3/3266; H01L 51/00; H01L 27/32

(52) U.S. Cl. CPC G09G 3/3266; H01L 27/3258; H01L 51/0096; H01L 27/12

(57) ABSTRACT

A display panel is disclosed, which includes: a substrate; a scan line disposed on the substrate and extending along a first direction, wherein a first reference line parallel to the first direction and locating on the scan line is defined; data lines disposed on the substrate and extending along a second direction different from the first direction; an insulating layer disposed on the substrate and having an opening; and a shielding pattern disposed between two adjacent data lines and overlapping the scan line, wherein the shielding pattern includes first and second regions, the first region overlaps the opening and has a first outer edge, and the second region is adjacent to the first region and has a second outer edge. A first distance between the first outer edge and the first reference line is greater than a second distance between the second outer edge and the second reference line.

### CROSS REFERENCE TO RELATED APPLICATION

This application claims the benefits of the Chinese Patent Application Serial Number 201610626922.2, filed on. Aug. 3, 2016, the subject matter of which is incorporated herein by reference.

### BACKGROUND

### 1. Field

The present disclosure relates to a display device and, more particularly, to a display device in which a specific structure between a shielding pattern and an insulating layer on the substrate is designed.

### 2. Description of Related Art

With the continuous advancement of technologies related to displays, all the display panels are now developed toward compactness, thinness, and lightness. This trend makes thin displays, such as liquid crystal display panels, organic light-emitting diode display panels and inorganic light-emitting diode display panels, replacing cathode-ray-tube displays as the mainstream display devices on the market.

In the commercial available display device, a shielding pattern may be formed on a thin film transistor substrate or on a counter substrate opposite to the thin film transistor substrate. When the shielding pattern is formed on the thin film transistor substrate, the shielding pattern may peel off at the interface between different layers because multiple layers are formed on the thin film transistor substrate. Therefore, it is desirable to provide a display device, which can solve the peeling problem of the shielding pattern to improve the yield of the display device.

### SUMMARY

An object of the present disclosure is to provide a display device, wherein a specific structure between a shielding pattern and an insulating layer on the substrate is designed to improve the adhesion between the shielding pattern and the insulating layer.

The display device of the present disclosure comprises: a substrate; a scan line disposed on the substrate and extending along a first direction, wherein a first reference line parallel to the first direction is defined, and the first reference line locates on the scan line in top view; a plurality of data lines disposed on the substrate and extending along a second direction, wherein the first direction and the second direction are different; an insulating layer disposed on the plurality of data lines, wherein the insulating layer has an opening; and a shielding pattern disposed on the insulating layer and between two adjacent data lines in top view, wherein the shielding pattern overlaps the scan line, the shielding pattern comprises a first region and a second region, the second pattern is adjacent to the first region, the first region overlaps the opening, the first region has a first outer edge, and the second region has a second outer edge. Herein, a first distance is between the first reference line and the first outer edge, a second distance is between the first reference line and the second outer edge, and the first distance is greater than the second distance.

In the display device of the present disclosure, the shielding pattern can be a black matrix layer.

In the display device of the present disclosure, the first distance between the first reference line and the first outer edge of the first region of the shielding pattern is greater than the second distance between the first reference line and the second outer edge of the second region of the shielding pattern, so the shielding pattern has a relative protruded structure at the opening of the insulating layer (especially, in a top view). Hence, the contact area of the shielding pattern at the opening can be increased. Therefore, the peeling of the shielding pattern due to the height difference generated at the opening can be prevented, and the adhesion of the shielding layer to other layers can be improved.

Other objects, advantages, and novel features of the disclosure will become more apparent from the following detailed description when taken in conjunction with the accompanying drawings.

### BRIEF DESCRIPTION OF THE DRAWINGS

FIG. 1A is a top view of a display device according to one embodiment of the present disclosure.

FIG. 1B is a cross sectional view of a display device according to one embodiment of the present disclosure.

FIGS. 2A and 2B are top views showing units on a substrate of a display device according to one embodiment of the present disclosure.

FIG. 3 is a cross sectional view of a display device at the line L1-L1′ indicated in FIGS. 2A and 2B.

FIG. 4 is a partial enlarged view of the display device of FIG. 2B.

FIG. 5 is a cross sectional view of a display device at the line L2-L2′ indicated in FIGS. 2A and 2B.

FIG. 6 is a partial enlarged view of the display device of FIG. 2B.

FIG. 7 is a cross sectional view of a display device at the line L3-L3′ indicated in FIGS. 2A and 2B.

FIG. 8 is a perspective view showing units on a substrate of a display device according to another embodiment of the present disclosure.

### DETAILED DESCRIPTION OF EMBODIMENT

The following embodiments when read with the accompanying drawings are made to clearly exhibit the above-mentioned and other technical contents, features and effects of the present disclosure. Through the exposition by means of the specific embodiments, people would further understand the technical means and effects the present disclosure adopts to achieve the above-indicated objectives. Moreover, as the contents disclosed herein should be readily understood and can be implemented by a person skilled in the art, all equivalent changes or modifications which do not depart from the concept of the present disclosure should be encompassed by the appended claims.

Furthermore, the ordinals recited in the specification and the claims such as “first”, “second”, “third” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

Furthermore, the ordinals recited in the specification and the claims such as “above”, “over”, or “on” are intended not only directly contact with the other substrate or film, but also intended indirectly contact with the other substrate or film.

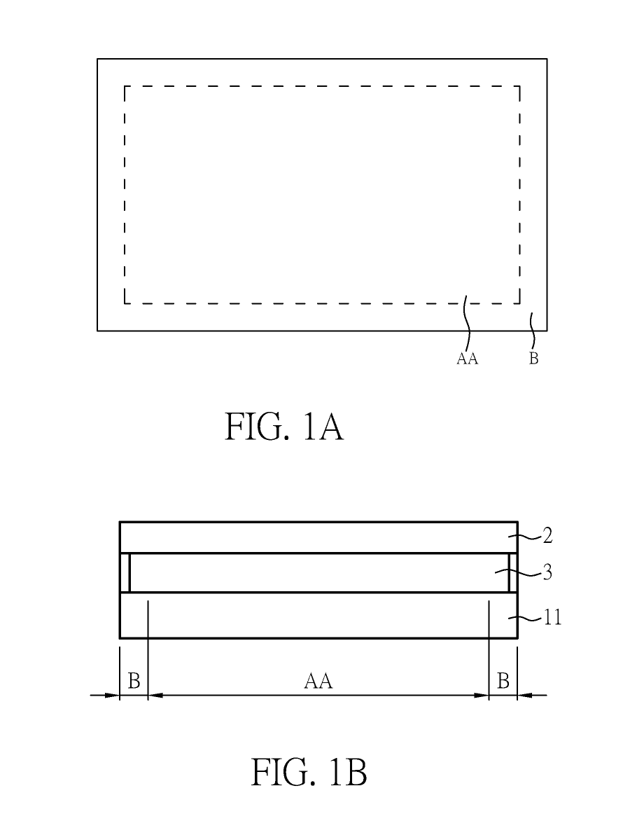

FIGS. 1A and 1B are respectively a top view (plan view, through the normal direction of device or substrate) and a cross sectional view (side view) of a display device according to one embodiment of the present disclosure. The display device of the present embodiment comprises: a substrate 11; a counter substrate 2 opposite to the substrate 11; and a display layer 3 disposed between the substrate 11 and the counter substrate 2. Herein, the display device comprises: a display region AA; and a periphery region B adjacent to the display region AA and locating outside the display region AA. The periphery region B is a region with circuits and wiring formed thereon, and the display region AA is a region with pixels formed thereon. In the present embodiment, transistors (not shown in the figure), a color filter layer (not shown in the figure) and a shielding layer (not shown in the figure) may be disposed on the substrate 11. However, in other embodiment of the present disclosure, the aforesaid color filter layer (not shown in the figure) or the aforesaid shielding layer (not shown in the figure) may be selectively formed on the counter substrate 2. In addition, in the present embodiment, the substrate 11 and the counter substrate 2 may be prepared by glass, plastic, flexible materials or thin films. When the substrate 11 and the counter substrate 2 are prepared by plastic, flexible materials or thin film, the obtained display device is a flexible display device. Furthermore, in the present embodiment, the shielding layer (not shown in the figure) is a black matrix layer.

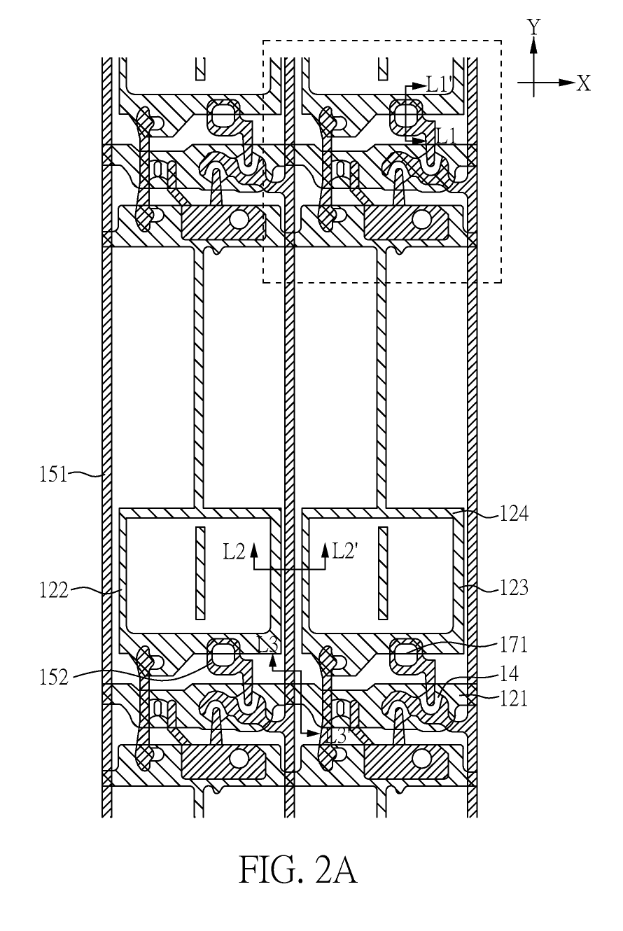

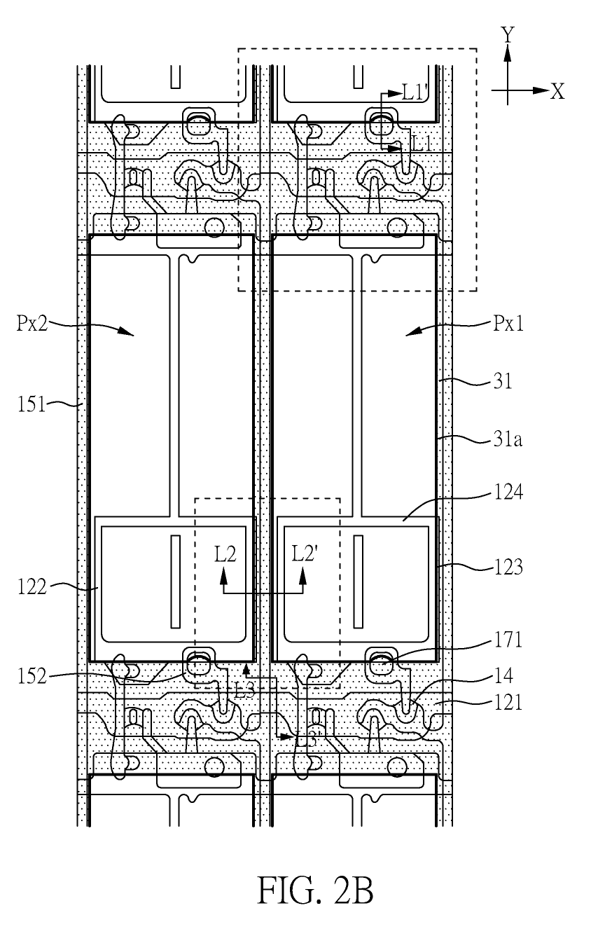

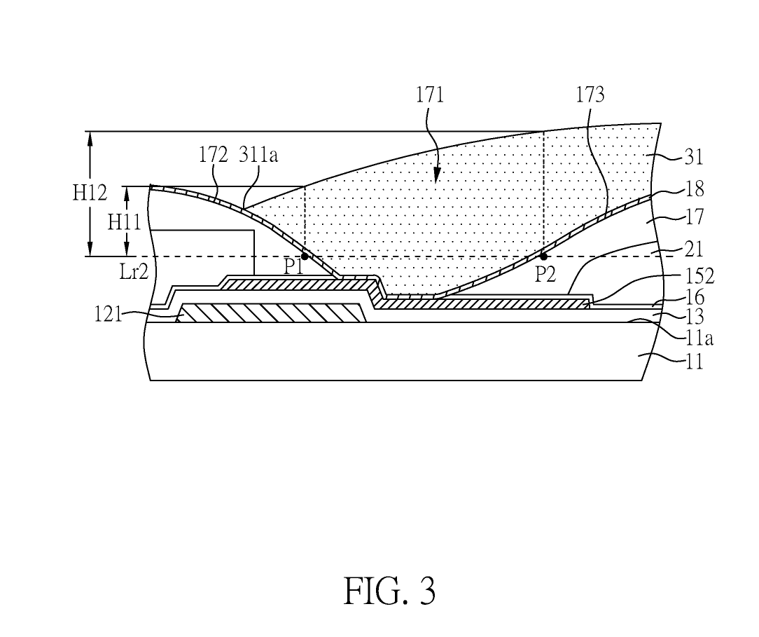

FIGS. 2A and 2B are top views showing units on the substrate of the display device of the present embodiment. The differences between FIGS. 2A and 2B is that hatching lines of some layers in FIG. 2A are not shown in FIG. 2B for simplification; and a shielding pattern is further added in FIG. 2B. In addition, FIG. 3 is a cross sectional view of the display device at the line L1-L1′ indicated in FIGS. 2A and 2B.

As shown in FIGS. 2A and 3, in the display device of the present embodiment, a first metal layer is firstly formed on the substrate 11, wherein the first metal layer comprises: a scan line 121, a first metal shielding pattern 122, a second metal shielding pattern 123 and a third metal shielding pattern 124. Next, a first insulating layer 13 is formed on the first metal layer, followed by forming an active layer 14 on the first insulating layer 13 in the region that a transistor to be formed. Next, a second metal layer is formed on the active layer 14, wherein the second metal layer comprises: a data line 151 and an electrode pad 152. The data line 151 and the electrode pad 152 are electrically connected to the active layer 14, and a part of the data line 151 and a part of the electrode pad 152 serve as source and drain of a transistor. Then, a second insulating layer 16 is formed on the second metal layer, followed by forming a color filter layer 21 on the second insulating layer 16.

As shown in FIGS. 2A and 3, an insulating layer 17 is formed on the color filter layer 21, and the insulating layer 17 has an opening 171 to expose a part of the second metal layer. As shown in FIG. 3, the opening 171 of the insulating layer 17 exposes a part of the electrode pad 152 of the second metal layer. Then, a first electrode layer 18 is formed on the insulating layer 17 and the exposed electrode pad 152, the first electrode layer 18 may electrically connect with the exposed electrode pad 152, followed by forming a shielding layer 31. As shown in FIGS. 2B and 3, the shielding layer 31 not only is formed in the opening 171 of the insulating layer 17, but also overlaps with the scan line 121, a part of the second metal shielding pattern 123, the data line 151 and a part of the electrode pad 152 in top view. Please refer to the boundary 31a of the shielding layer 31 shown in FIG. 2B. After the aforementioned process, the transistor, the color filter layer and the shielding layer on the substrate are formed.

In the present embodiment, the display device further comprises a color filter layer 21 disposed on the substrate 11 and between the insulting layer 17 and the substrate 11. However, in other embodiment of the present disclosure, the color filter layer 21 may be disposed on the counter substrate 2 (as shown in FIG. 1B).

In the present embodiment, the display device can be a liquid crystal display (LCD) device. In this case, the first electrode layer 18 can be used as a pixel electrode. In addition, an alignment layer (not shown in the figure) may be further disposed on the shielding layer 31 and the exposed first electrode layer 18.

However, the display device of the present disclosure is not limited to the LCD device, and can be an organic light emitting diode (OLED) display device, an inorganic light emitting diode with micrometer size (micro-LED) display device or a quantum dot light emitting diode (QLED) display device. When the display device of the present disclosure is an OLED display device, micro-LED display device or QLED display device, the color filter layer 21 may be disposed on the substrate 11 or the counter substrate 2 (as shown in FIG. 1B); or the display device is not equipped with the color filter layer. In addition, the units on the substrate 11 may further comprise other layers for forming the organic light emitting diode, micro-LED, or QLED, such as an organic light emitting layer, an inorganic light emitting layer, a quantum dot light emitting layer and a second electrode layer. For example, the organic layer may, the inorganic light emitting layer, or the quantum dot light emitting layer be disposed between the first electrode layer 18 shown in FIG. 3 and the second electrode layer.

Furthermore, the display device of the present disclosure is not limited to the aforesaid display device. The display layer 3 can be fluorescence, and thus the display device can be a fluorescence display device.

In the display device of the present embodiment, the first insulating layer 13, the second insulating layer 16 and the insulating layer 17 may comprise silicon oxides, silicon nitrides or silicon nitroxides. The first metal layer (including the scan line 121, the first metal shielding pattern 122, the second metal shielding pattern 123 and the third metal shielding pattern 124) and the second metal layer (including the data line 151 and the electrode 152) may comprise conductive materials such as metals (e.g., Cu, Mg, Mo, Ti, Al, Cr, Ag, etc.), alloys, metal oxides, metal nitroxides or other electrode materials. The first electrode layer 18 may comprise transparent electrode material such as ITO, IZO or ITZO. However, in other embodiment of the present disclosure, the materials comprised in the aforesaid units are not limited thereto.

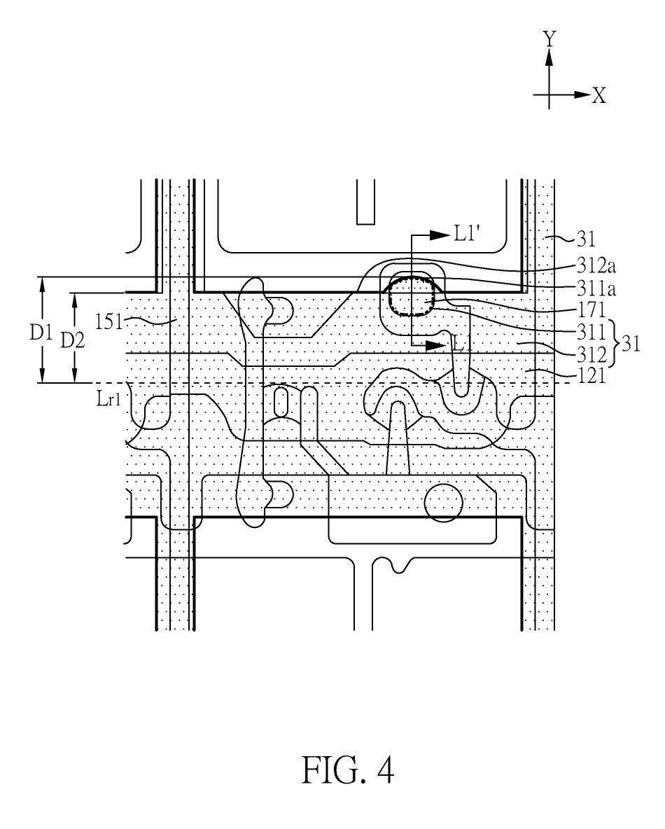

FIG. 4 is a partial enlarged view of the display device of FIG. 2B. As shown in FIGS. 3 and 4, the display device of the present embodiment comprises: a substrate 11; a scan line 21 disposed on the substrate 11 and extending along a first direction X, wherein a first reference line Lr1 parallel to the first direction X is defined, and the first reference line Lr1 locates on the scan line 121; plural data lines 151 disposed on the substrate 11 and extending along a second direction Y, wherein the first direction X and the second direction Y are different; an insulating layer 17 disposed on the substrate 11, wherein the insulating layer 17 has an opening 171; and a shielding layer 31 disposed between two adjacent data lines 151, wherein the shielding layer 31 overlaps the scan line 121 in top view. More specifically, the insulating layer 17 is disposed on the data line 151, and the shielding layer 31 is disposed on the insulating layer 17 and the shielding layer 31 overlaps a part of the insulating layer 17 and in the opening 171 in top view.

In the present embodiment, the first direction X is substantially vertical to the second direction Y. Here, the term “substantially vertical” refers to that an included angle between the first direction X and the second direction Y is between 85 degree and 90 degree. However, the present disclosure is not limited thereto. Other embodiments, as long as the first direction X and the second direction Y are different, are within the scope of the present disclosure.

As shown in FIG. 4, in the display device of the present embodiment, the shielding layer 31 comprises a first region 311 and a second region 312, the second region 312 is adjacent to the first region 311, the first region 311 is the portion of the shielding layer 31 in the opening 171, and the second region 312 is the region the shielding layer 31 except the first region 311, and the first region 311 overlaps the opening 171 of the insulating layer 17 in top view. Herein, the first region 311 has a first outer edge 311a, the second region 312 has a second outer edge 312a adjacent to the opening 171, and the first outer edge 311a is adjacent to the second outer edge 312a. A first distance D1 is between the first reference line Lr1 and the first outer edge 311a in a direction perpendicular to the first direction X (e.g., the second direction Y), a second distance D2 is between the first reference line Lr1 and the second outer edge 312a in a direction perpendicular to the first direction X (e.g., the second direction. Y), and the first distance D1 is greater than the second distance D2.

As shown in FIGS. 3 and 4, the shielding layer 31 is disposed in the opening 171 of the insulating layer 17. Thus, for the shielding layer 31, a height difference exists at the opening 171 of the insulating layer 17. More specifically, a height difference exists between the bottom portion of the opening 171 of the insulating layer 17 and the upper surface (for example, the first inclined surface 172) of the insulating layer 17; and the shielding layer 31 may peel off at the opening 171 of the insulating layer 17 due to the height difference. Hence, in the display device of the present embodiment, the first distance D1 between the first reference line Lr1 and the first outer edge 311a of the first region. 311 of the shielding layer 31 at the opening 171 of the insulating layer 17 is increased to be greater than the second distance D2 between the first reference line Lr1 and the second outer edge 312a of the second region 312. Hence, the contact area of the first region 311 of the shielding layer 31 at the opening 171 of the insulating layer 17 is increased to improve the adhesion of the first region 311 of the shielding layer 31. Therefore, the peeling of the shielding layer 31 at the opening 171 of the insulating layer 17 can be prevented.

In the present embodiment, as shown in FIG. 3, the opening 171 of the insulating layer 17 has a first inclined surface 172, and the first outer edge 311a of the shielding layer 31 locates on the first inclined surface 172. In addition, in the display device of the present embodiment, in a second cross section passing through the opening 171 of the insulting layer 17 (i.e. the cross sectional view shown in FIG. 3), the opening 171 of the insulating layer 17 has a first inclined surface 172 and a second inclined surface 173, and the shielding layer 31 overlaps a portion of the first inclined surface 172 and overlaps at least a portion of the second inclined surface 173. Furthermore, in this second cross section (i.e. the cross sectional view shown in FIG. 3), a second reference line Lr2 parallel to a substrate surface 11a of the substrate 11 and passing through the insulating layer 17 is defined, a first intersection point P1 is formed by the second reference line Lr2 and the first inclined surface 172, a second intersection point P2 is formed by the second reference line Lr2 and the second inclined surface 173, and a height H11 from top surface of the shielding layer 31 to the first intersection point P1 in the direction perpendicular to the substrate surface 11a is different from a height 1112 from top surface of the shielding layer 31 to the second intersection point P2 in the direction perpendicular to the substrate surface 11a. In the present embodiment, the height H11 is less than the height 1112. However, in other embodiment, the height H11 may be greater than the height H12. Herein, the “height H11” and the “height H12” respectively refer to distances between the surface of the shielding layer 31 and the first intersection point P1 or the second intersection point P2 at a direction perpendicular to the substrate surface 11a.

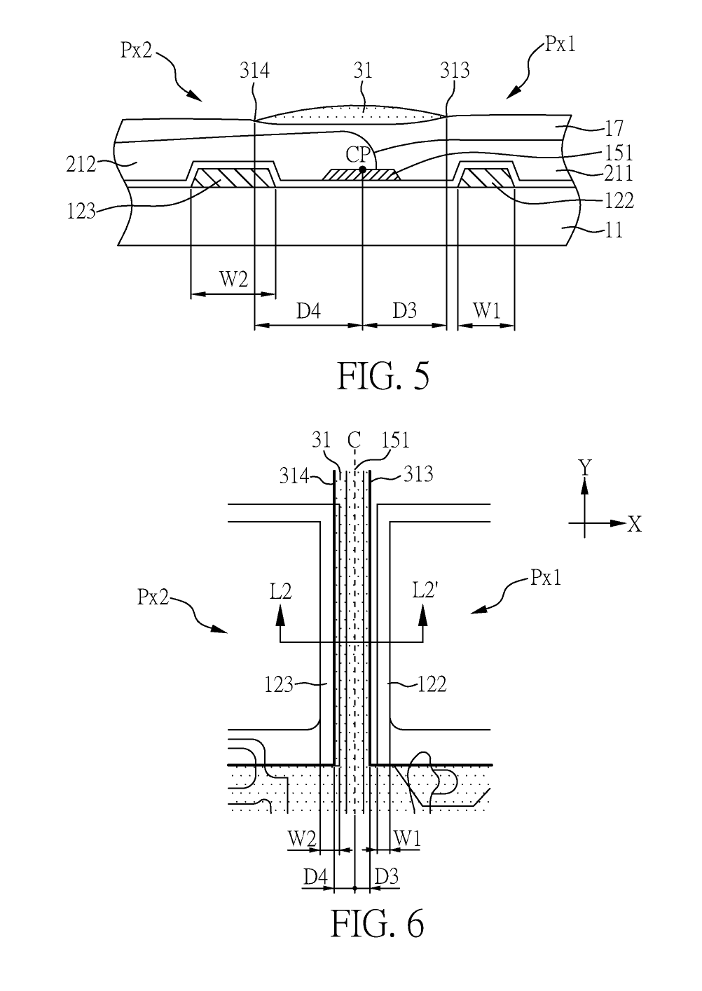

FIG. 5 is a cross sectional view of the display device at the line L2-L2′ indicated in FIGS. 2A and 2B; and FIG. 6 is a partial enlarged view of the display device of FIG. 2B. In the display device of the present embodiment, as shown in FIG. 5 which is the first cross section at the first direction X or FIG. 6 which is the top view, the shielding layer 31 further overlaps the data line 151, the shielding layer 31 has a first edge 313 and a second edge 314, the first edge 313 and the second edge 314 respectively locate at two sides of the data line 151, the data line 151 has a central line C (a central point CP in FIG. 5), a third distance D3 is between the first edge 313 and the central line C (or the central point CP), a fourth distance D4 is between the second edge 314 and the central line C (or the central point CP), and the third distance D3 and the fourth distance D4 are different. Herein, the “third distance D3” and the “fourth distance D4” respectively refer to distances between the projected first edge 313/second edge 314 and the projected central line C/central point CP on the substrate 11.

As shown in FIGS. 5 and 6, the display device of the present embodiment further comprises a first metal shielding pattern 122 and a second metal shielding pattern 123, wherein the first metal shielding pattern 122 and the second metal shielding pattern 123 respectively extend along the second direction Y and are disposed at two sides of the data line 151. The first side 313 of the shielding layer 31 is close to the first metal shielding pattern 122, the second side 314 of the shielding layer 31 is close to the second metal shielding pattern 123, a width W2 of the second metal shielding pattern 123 is greater than a width W1 of the first metal shielding pattern 122, and the third distance D3 is less than the fourth distance D4.

Herein, the width W1 of the first metal shielding pattern 122 and the width W2 of the second metal shielding pattern 123 are different. In particular, the width W2 is greater than the width W1. Hence, when forming the shielding layer 31, it is preferable to make the shielding layer 31 close to the second metal shielding pattern 123 with a larger width (W2) in comparison with the width (W1) the first metal shielding pattern 122. More specifically, on the basis of the central line C or the central point CP of the data line 151, the third distance D3 between the first side 313 of the shielding layer 31 and the central line C or the central point CP is not equal to the fourth distance D4 between the second side 314 and the central line C or the central point CP. In addition, the fourth distance D4 between the central line C/the central point CP and the second side 314 of the shielding layer 31 which is close to the second metal shielding pattern 123 with the larger width is better, compared to the third distance D3 between the central line C/the central point CP and the first side 313 of the shielding layer 31 which is close to the first metal shielding pattern 122 with the smaller width. In other word, the shielding layer 31 is designed to be closer to the second metal shielding pattern 123 with the larger width. Therefore, the transmittance of the display device can be improved. In the present embodiment, as shown in FIGS. 2A and 2B, in a single pixel, the first metal shielding pattern 122, the second metal shielding pattern 123 and other parts (for example, the third metal shielding pattern 124 extending along the first direction X) are configured into a metal shielding pattern with special shape. However, in other embodiments of the present disclosure, the shape of the metal shielding pattern is not limited thereto and the metal shielding pattern may have other shapes.

In addition, as shown in FIGS. 5 and 6, in the display device of the present embodiment, the second side 314 further locates on the second metal shielding pattern 123.

Furthermore, as shown in FIGS. 2A and 2B, the display device of the present embodiment comprises plural scan lines 121, wherein plural pixels are defined by the scan lines 121 and the data lines 151, the pixels comprises a first sub-pixel Px1 and a second sub-pixel Px2, the sub-pixels are enclosed by the scan lines 121 and the data lines 151, and the first sub-pixel Px1 is adjacent to the second sub-pixel Px2. The first sub-pixel Px1 is a green sub-pixel (i.e. the first resin 211 in the color filter layer shown in FIG. 5 is a green resin), and the second sub-pixel Px2 is a non-green sub-pixel (i.e. the second resin 212 in the color filter layer shown in FIG. 5 is a non-green resin). In the present embodiment, the non-green sub-pixel may be a blue sub-pixel, a red sub-pixel, a white sub-pixel or a yellow sub-pixel, but the present disclosure is not limited thereto.

As shown in FIGS. 5 and 6, in the display device of the present embodiment, the first edge 313 of the shielding layer 31 locates on the first sub-pixel Px1, the second edge 314 of the shielding layer 31 locates on the second sub-pixel Px2, and the third distance D3 is less than the fourth distance D4. Because human eyes are most sensitive to green light, the shielding layer 31 (especially, the center of the shielding layer 31) is designed to be more far from the green sub-pixel when forming the shielding layer 31 to improve the transmittance of the green sub-pixel. More specifically, on the basis of the central line C or the central point CP of the data line 151, the distance D3 between the first side 313 of the shielding layer 31 and the central line C or the central point CP is not equal to the fourth distance D4 between the second side 314 and the central line C or the central point CP. In addition, compared to the third distance D3 between the first side 313 and the central line C or the central point CP in the first sub-pixel Px1 which is a green sub-pixel, the fourth distance D4 between the central line C/the central point CP and the second side 314 of the shielding layer 31 in the non-green pixel unit Px2 is greater. In other word, the shielding pattern 31 (especially, the center of the shielding pattern 31) is designed to be far from the first sub-pixel Px1 which is a green sub-pixel and to be close to the second sub-pixel Px2 which is a non-green sub-pixel, to improve the transmittance of the display device.

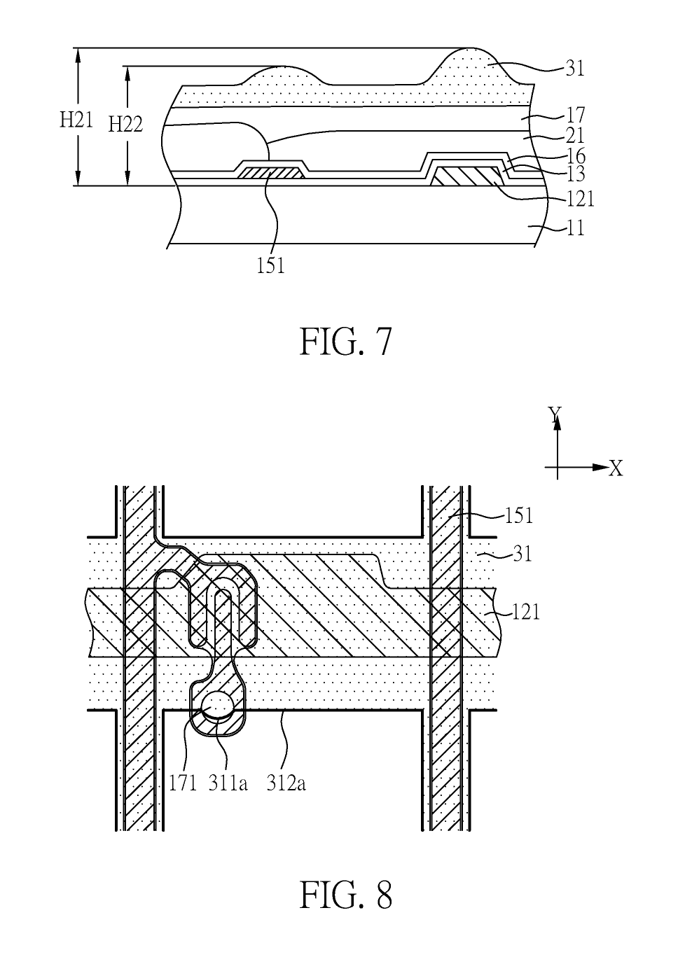

FIG. 7 is a cross sectional view of a display device at the line L3-L3′ indicated in FIGS. 2A and 2B. As shown in FIGS. 2B and 7, the display device of the present embodiment comprises plural scan line 121, wherein the shielding layer 31 overlaps the scan lines 121 and the data lines 151, a first height 1121 is between the substrate 11 and the shielding layer 31 locating on at least one of the scan lines 121, a second height H22 is between the substrate 11 and the shielding layer 31 locating on at least one of the data line 151, and the first height 1121 is greater than the second height 1122. Herein, the first height 1121 is between the substrate 11 and a surface of the shielding layer 31 locating on the at least one of the scan lines 121, a second height H22 is between the substrate 11 and the surface of the shielding layer 31 locating on the at least one of the data line 151.

FIG. 8 is a perspective view showing units on a substrate of a display device according to another embodiment of the present disclosure. The display device of the present embodiment is similar to those illustrated before, and especially the features of the shielding pattern (i.e. the black matrix layer) of the present embodiment are similar to those illustrated above. The main difference is that the display device of the present embodiment is not equipped with metal shielding pattern.

When the display device of the present disclosure is a LCD device, the display device may further comprise a backlight module (not shown in the figure) disposed below the substrate 11 shown in FIG. 1B.

A display device made as described in any of the embodiments of the present disclosure as described previously may be integrated with a touch panel to form a touch display device. Moreover, a display device or touch display device made as described in any of the embodiments of the present disclosure as described previously may be applied to any electronic devices known in the art that need a display screen, such as displays, mobile phones, laptops, video cameras, still cameras, music players, mobile navigators, TV sets, and other electronic devices that display images.

Although the present disclosure has been explained in relation to its embodiment, it is to be understood that many other possible modifications and variations can be made without departing from the spirit and scope of the disclosure as hereinafter claimed.

What is claimed is:

1. A display device, comprising:
a substrate;
a scan line disposed on the substrate and extending along a first direction, wherein a first reference line parallel to the first direction is defined, and the first reference line locates on the scan line in top view;
a plurality of data lines disposed on the substrate and extending along a second direction, wherein the first direction and the second direction are different;
an insulating layer disposed on the plurality of data lines, wherein the insulating layer has an opening; and
a shielding pattern disposed on the insulating layer, wherein, in top view; the shielding pattern is disposed between two adjacent data lines, and the shielding pattern overlaps the scan line,
wherein the shielding pattern comprises a first region and a second region adjacent to the first region, the first region overlaps the opening, the first region has a first outer edge, and the second region has a second outer edge,
wherein a distance between the first reference line and the first outer edge in top view is defined as a first distance, a distance between the first reference line and the second outer edge in top view is defined as a second distance, and the first distance is greater than the second distance.

2. The display device of claim 1, wherein the first outer edge is adjacent to the second outer edge.

3. The display device of claim 1, wherein the shielding pattern overlaps a part of the insulating layer and at least a part of the opening.

4. The display device of claim 1, wherein in a first cross section of the display device along the first direction, a portion of the shielding layer overlaps one of the plurality of data lines, the portion of the shielding layer has a first edge and a second edge, the first edge and the second edge respectively locate at two sides of the data line, the data line has a central point, a third distance is between the first edge and the central point, a fourth distance is between the second edge and the central point, and the third distance and the fourth distance are different.

5. The display device of claim 4, further comprising a plurality of scan lines and a plurality of pixels, one of the plurality of pixels comprises a first sub-pixel and a second sub-pixel, the first sub-pixel is adjacent to the second sub-pixel, a color of the first sub-pixel is green, and a color the second sub-pixel is not green; wherein the first edge of the shielding pattern locates corresponding to the first sub-pixel, the second edge of the shielding pattern locates corresponding to the second sub-pixel, and the third distance is less than the fourth distance.

6. The display device of claim 5, wherein the color of the second sub-pixel is blue, red, white or yellow.

7. The display device of claim 4, further comprising a first metal shielding pattern and a second metal shielding pattern, wherein the first metal shielding pattern and the second metal shielding pattern respectively extend along the second direction and are disposed at two sides of the data line, the first side is close to the first metal shielding pattern, the second side is close to the second metal shielding pattern, a width of the second metal shielding pattern is greater than a width of the first metal shielding pattern, and the third distance is less than the fourth distance.

8. The display device of claim 7, wherein the second side locates corresponding to the second metal shielding pattern.

9. The display device of claim 7, wherein the shielding pattern overlaps a part of the second metal shielding pattern in top view.

10. The display device of claim 1, wherein the opening has a first inclined surface, and the first outer edge of the shielding pattern locates corresponding to the first inclined surface.

11. The display device of claim 1, wherein in a second cross section passing through the opening of the insulting layer of the display device, the opening of the insulating layer has a first inclined surface and a second inclined surface, and the shielding pattern overlaps a portion of the first inclined surface and at least a portion of the second inclined surface.

12. The display device of claim 1, wherein in a second cross section passing through the opening of the insulting layer of the display device, the opening of the insulating layer has a first inclined surface and a second inclined surface; wherein, a second reference line parallel to a surface of the substrate and passing through the insulating layer in top view is defined, a first intersection point is formed by the second reference line and the first inclined surface, a second intersection point is formed by the second reference line and the second inclined surface, and a height from the shielding pattern to the first intersection point is different from a height from the shielding pattern to the second intersection point.

13. The display device of claim 12, wherein a height from a surface of the shielding pattern to the first intersection point is different from a height from the surface of the shielding pattern to the second intersection point at a direction perpendicular to the substrate surface.

14. The display device of claim 1, further comprising a plurality of scan lines, wherein the shielding pattern overlaps the plurality of scan lines and the plurality of data lines, a first height is between the substrate and the shielding pattern locating on at least one of the plurality of scan lines, a second height is between the substrate and the shielding pattern locating on at least one of the plurality of data lines, and the first height is greater than the second height.

15. The display device of claim 14, wherein the first height is between the substrate and a surface of the shielding pattern locating on the at least one of the plurality of scan lines, and the second height is between the substrate and the surface of the shielding pattern locating on the at least one of the plurality of data lines.

16. The display device of claim 1, further comprising a counter substrate and a display layer, wherein the counter substrate is opposite to the substrate, and the display layer is disposed between the substrate and the counter substrate.

17. The display device of claim 1, further comprising a color filter layer, wherein the color filter layer is disposed between the insulating layer and the substrate.

18. The display device of claim 1, wherein the shielding layer is a black matrix layer.
